(19) United States
(12) Patent Application Publication
(10) Pub. No.: US 2022/0018875 A1
(43) Pub. Date: Jan. 20, 2022

(54) CONTACT PIN AND SOCKET

(71) Applicant: Enplas Corporation, Kawaguchi-shi, Saitama (JP)

(72) Inventor: Yoshinobu Hagiwara, Saitama (JP)

(21) Appl. No.: 17/289,330

(22) PCT Filed: Oct. 28, 2019
(86) PCT No.: PCT/JP2019/042185

§ 371 Date: Apr. 28, 2021

(30) Foreign Application Priority Data
Oct. 29, 2018 (JP) 2018-203016

(51) Int. Cl. G01R 1/067; G01R 1/04; G01R 31/28

(52) U.S. Cl. CPC G01R 1/06722; G01R 1/06733; G01R 31/2863; G01R 1/0466

(57) ABSTRACT

A contact pin includes: a first contact portion provided on one end side in a first direction; a second contact portion provided on another end side in the first direction; and an elastically deformable spring portion provided on a middle portion between the first contact portion and the second contact portion, wherein the first contact portion, the second contact portion, and the middle portion are integrally formed, and the first contact portion includes a plurality of cut sections each being displaceable in the first direction.

### TECHNICAL FIELD

The present invention relates to a contact pin and a socket.

### BACKGROUND ART

A sockets have been used for inspecting electrical components such as IC packages as described in, for example, Patent Literature (hereinafter, referred to as “PTL”) 1. Such sockets are provided with a plurality of contact pins that electrically connect an electrical component and a board for inspection (hereinafter also referred to as “inspection board”), which is a board on the inspection device side.

Each contact pin includes, at its upper end part, a first contact portion that comes into contact with a terminal of the electrical component, a curved spring portion at its middle part, and, at its lower end part, a second contact portion that comes into contact with a terminal of the inspection board.

### CITATION LIST

### Patent Literature

### PTL 1

Japanese Patent Application Laid-Open No. 2006-294456

### SUMMARY OF INVENTION

### Technical Problem

In a contact pin such as that described above, there is a demand for an improvement in the conductivity that allows flow of a high current.

The present invention has been made in view of such a demand, and an object thereof is to improve the conductivity so as to support a high current.

### Solution to Problem

For solving the above described disadvantages in the conventional art, a contact pin of the present invention is provided with: a first contact portion provided on one end side in a first direction; a second contact portion provided on another end side in the first direction; and an elastically deformable spring portion provided on a middle portion between the first contact portion and the second contact portion, wherein the first contact portion, the second contact portion, and the middle portion are integrally formed, and the first contact portion includes a plurality of cut sections each being displaceable in the first direction.

For solving the above described disadvantages in the conventional art, a socket of the present invention is provided with: a contact pin; and a support including a through hole into which the contact pin is inserted.

### Advantageous Effects of Invention

The present invention is capable of improving the conductivity to support a high current.

### BRIEF DESCRIPTION OF DRAWINGS

FIG. 1A is an overall perspective view of a contact pin according to a first embodiment of the present invention;

FIG. 1B is an enlarged perspective view of FIG. 1A to illustrate an upper contact portion of the contact pin according to the first embodiment of the present invention;

FIG. 2 is a cross-sectional view of a configuration of a socket according to the first embodiment of the present invention;

FIG. 3A is an overall perspective view of a contact pin according to a second embodiment of the present invention;

FIG. 3B is an enlarged perspective view of FIG. 3A to illustrate an upper contact portion of the contact pin according to the second embodiment of the present invention;

FIG. 4A is an overall perspective view of a modification of the contact pin according to the second embodiment of the present invention;

FIG. 4B is an enlarged perspective view of FIG. 4A to illustrate an upper contact portion of the modification of the contact pin according to the second embodiment of the present invention;

FIG. 5A is an overall perspective view of a contact pin according to a third embodiment of the present invention;

FIG. 5B is an enlarged perspective view of FIG. 5A to illustrate an upper contact portion of the contact pin according to the third embodiment of the present invention;

FIG. 6A is an overall perspective view of a contact pin according to a fourth embodiment of the present invention; and

FIG. 6B is an enlarged perspective view of FIG. 6A to illustrate an upper contact portion of the contact pin according to the fourth embodiment of the present invention.

### DESCRIPTION OF EMBODIMENTS

Hereinafter, a contact pin and a socket according to embodiments of the present invention will be described with reference to the drawings. The embodiments described below are merely an example, and do not exclude various modifications and the application of techniques which are not specified in the following embodiments. In addition, the configuration of each embodiment can be variously modified and implemented without departing from the scope of the embodiment. Configurations of the embodiments can also be selected or combined as needed.

In the following embodiments, for convenience, the contact pin will be described assuming that the first contact portion is placed on the upper side, the second contact portion is placed on the lower side, and a thickness direction is set in a front-rear direction. However, it is needless to say that the arrangement of the contact pins and sockets is not limited to such an arrangement.

In addition, the direction in which the spring portion (curved spring portion) bulges is defined as the front, and the opposite direction is defined as the rear, and thus, the left and right are determined based on the front.

In all the drawings for describing the embodiments, an element the same as a precedent element is given, in principle, the same reference numeral, and the description thereof may be omitted.

Hereinafter, a contact pin and a socket according to an embodiment of the present invention will be described in detail with reference to the drawings.

### 1. First Embodiment

### 1-1. Configurations

### 1-1-1. Configuration of Contact Pin

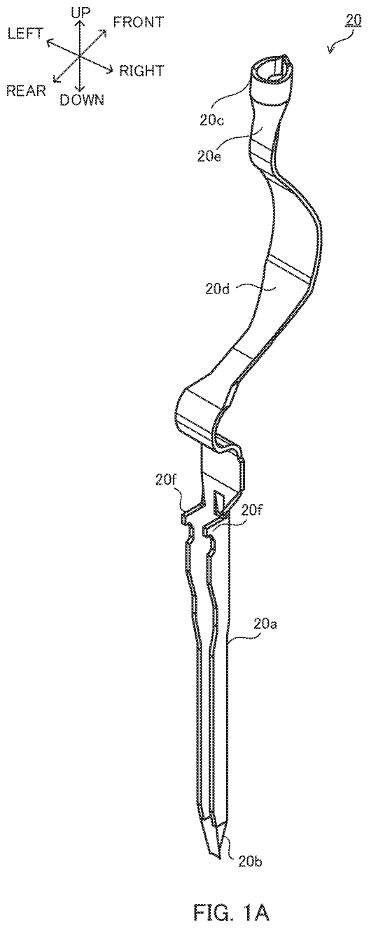

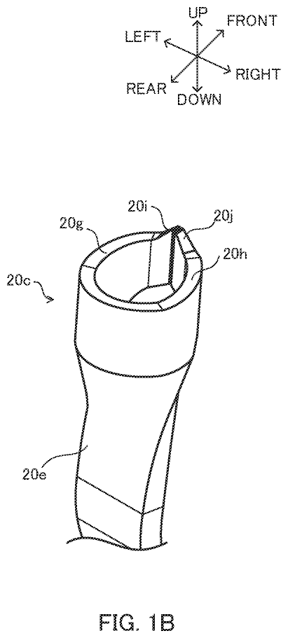

A configuration of a contact pin of a first embodiment in the present invention will be described with reference to FIGS. 1A and 1B. FIGS. 1A and 1B illustrate a configuration of the contact pin, in which FIG. 1A is an overall perspective view of the contact pin, and FIG. 1B is an enlarged perspective view of FIG. 1A to illustrate upper contact portion 20c (first contact portion).

Contact pin 20 illustrated in FIGS. 1A and 1B is formed by pressing a metal plate material excellent in conductivity. Contact pin 20 extends in a vertical direction (first direction) and includes press-fitting portion 20a, lower contact portion 20b (second contact portion), upper contact portion 20c, curved spring portion 20d (spring portion), and straight portion 20e. Press-fitting portion 20a is formed into a straight shape. Lower contact portion 20b extends from the lower end of press-fitting portion 20a and is formed into a tapered shape. Upper contact portion 20c is placed at the uppermost part of contact pin 20. Curved spring portion 20d is placed between upper contact portion 20c and press-fitting portion 20a and is curved in an arc shape. Straight portion 20e extends upward from the upper end of curved spring portion 20d and is connected to upper contact portion 20c.

A cross-section of press-fitting portion 20a exhibits a generally U-shape, and a pair of slightly wide stopper pieces 20f is formed on the upper part of press-fitting portion 20a.

Curved spring portion 20d includes a portion in which an upper portion of contact pin 20 is curved so that a predetermined elastic force can be obtained. When a pressing force is applied to contact pin 20 in the axial direction (vertical direction in the present embodiment), curved spring portion 20d is elastically deformed in a state where the curvature radius becomes smaller so as to shorten the total length of contact pin 20 and generate a reaction force trying to extend contact pin 20 upward.

Contact pin 20 has a width in a horizontal direction (second direction intersecting the first direction, hereinafter referred to as a “width direction”), and first cut section 20g is provided on one side of the width direction of the uppermost part while second cut section 20h is provided on the other side of the width direction. Each of first cut section 20g and second cut section 20h has a curved shape, in particular, a generally semi-cylindrical shape, such that the tips thereof are adjacent to each other. First cut section 20g and second cut section 20h form upper contact portion 20c that has a generally cylindrical shape. Moreover, tapered contact point 20i is provided on the upper end of the tip of first cut section 20g in a projecting manner. Similarly, tapered contact point 20j is provided on the upper end of the tip of second section 20h in a projecting manner.

Further, first cut section 20g and second cut section 20h are formed thinner than the other portions of contact pin 20 and are configured to be displaceable in the vertical direction.

### 1-1-2. Configuration of Socket

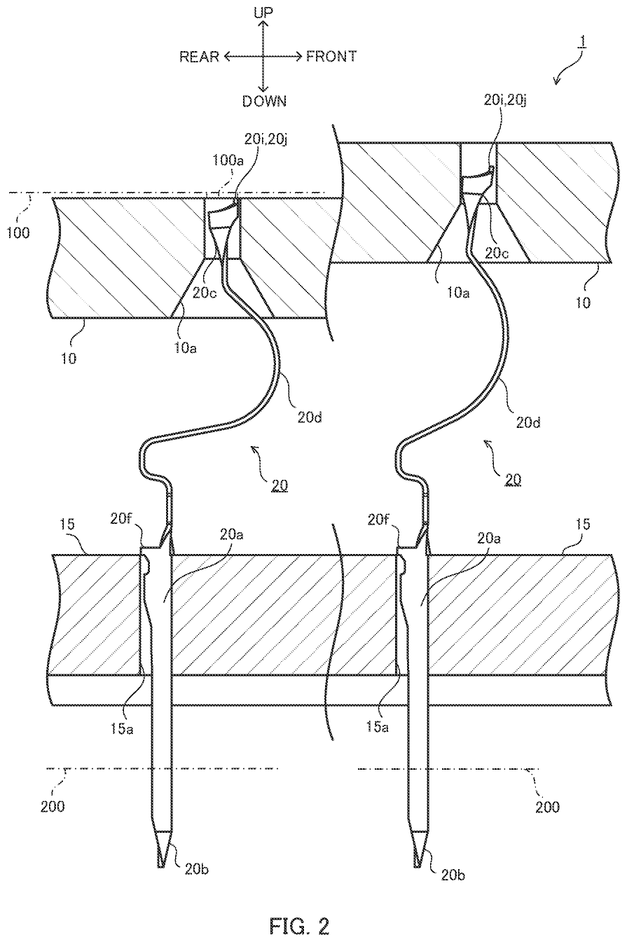

A description will be given of a configuration of a socket of a first embodiment of the present invention with reference to FIG. 2. FIG. 2 is a cross-sectional view of the configuration of the socket. In FIG. 2, for convenience, two different states of the socket are illustrated side by side. Note that, in FIG. 2, IC package 100 and wiring board 200 are illustrated by a dash-dotted line, for convenience.

Socket 1 illustrated in FIG. 2 is for electrically connecting pad 100a that is a terminal of IC package 100 and wiring board 200 in order to execute a performance test of IC package 100. The terminal of IC package 100 may be a solder ball.

Socket 1 includes floating plate 10, base member 15 (support), and contact pin 20.

A plurality of pads 100a as terminals are arranged in a matrix form on the bottom surface of IC package 100 connected to socket 1. A plurality of contact pins 20 are arranged in a matrix form so as to correspond to the arrangement of pads 100a.

Above the base member 15, floating plate 10 is provided detachably from base member 15. Floating plate 10 is energized upward by a coil spring (not illustrated).

Floating plate 10 is provided with a plurality of through holes 10a penetrating floating plate 10 in the vertical direction. Contact pin 20 is inserted through each through hole 10a, and an arrangement of through holes 10a corresponds to an arrangement of contact pins 20, that is, the arrangement of pads 100a of IC packages 100. Further, a horizontally cut surface of each through hole 10a has a circular shape. Specifically, each through hole 10a is provided with a cylindrical portion at the upper part thereof and a truncated cone-shaped portion at the lower part thereof, the diameter of which increases toward the lower side.

Similarly, base member 15 is provided with a plurality of through holes 15a penetrating base member 15 in the vertical direction. Contact pin 20 is inserted through each through hole 15a, and an arrangement of through holes 15a corresponds to an arrangement of contact pins 20, that is, the arrangement of pads 100a and the arrangement of through holes 10a. Further, a horizontally cut surface of through hole 15a has a circular shape.

Each contact pin 20 is inserted into through hole 10a and through hole 15a aligned with each other in the vertical direction. Specifically, press-fitting portion 20a of each contact pin 20 is press-fitted from the upper side into through hole 15a of base member 15 down to a position where the lower surface of stopper piece 20f is brought into contact with the upper surface of base member 15. As a result, as illustrated in FIG. 2, lower contact portion 20b protrudes downward from the bottom surface of base member 15. Thus, lower contact portion 20b is inserted into a through hole serving as a contact point provided in wiring board 200 (not illustrated), and is soldered from the lower surface side of wiring board 200 and thus electrically conducted to the contact point of wiring board 200.

An outline of how to use socket 1 will be described. Socket 1 is placed on wiring board 200 in advance, and lower contact portion 20b of contact pin 20 is inserted through wiring board 200. Lower contact portion 20b is, then, soldered to the through hole serving as a contact point of wiring board 200. As a result, socket 1 is in the state illustrated on the right side of FIG. 2.

Next, IC package 100 is set on the upper surface of floating plate 10 to press IC package 100 downward. As a result, floating plate 10 is pressed downward against the energizing force of the coil spring.

Thus, the state illustrated on the left side of FIG. 2 is obtained. Specifically, contact points 20i and 20j arranged adjacent to upper contact portion 20c are simultaneously brought into contact with the same pad 100a of IC package 100. When floating plate 10 is further pressed downward, curved spring portion 20d is elastically deformed, so that the energizing force is generated in curved spring portion 20d. As a result, contact points 20i and 20j of upper contact portion 20c are pressed by pad 100a of IC package 100 with a predetermined contact pressure.

In this state, a burn-in test or the like is executed by causing a current to flow through IC package 100.

### 1-1-3. Operational Effect

According to the first embodiment of the present invention, the following operational effects are obtained.

(1) In contact pin 20, when IC package 100 is pressed downward, contact point 20i of first cut section 20g and contact point 20j of second cut section 20h are simultaneously brought into contact with the same pad 100a of IC package 100.

Further, first cut section 20g and second cut section 20h are displaceable upward and downward. Thus, even when the height of contact point 20i of first cut section 20g and the height of contact point 20j of second cut section 20h are different due to, for example, a manufacturing error or wear, contact point 20i and contact point 20j are individually displaced downward while IC package 100 is pressed, so that the difference can be absorbed by the displacements. Moreover, at this time, a stronger reaction force is generated in the higher one of contact points 20i and 20j, and the higher contact point presses against pad 100a of IC package 100 more strongly.

Consequently, a plurality of contact points (two contact points 20i and 20j in the present embodiment) are simultaneously brought into contact with contact pad 100a of IC package 100, while the contact between contact pin 20 and pad 100a is stabilized. As a result, the conductivity of the contact pin can be improved than before, contact pin 20 and socket 1 can support a high current.

Further, since first cut section 20g and second cut section 20h have a relatively simple shape which is curved like an arc, upper contact portion 20c, that is, contact pin 20 can be easily manufactured.

### 2. Second Embodiment

### 2-1. Configuration

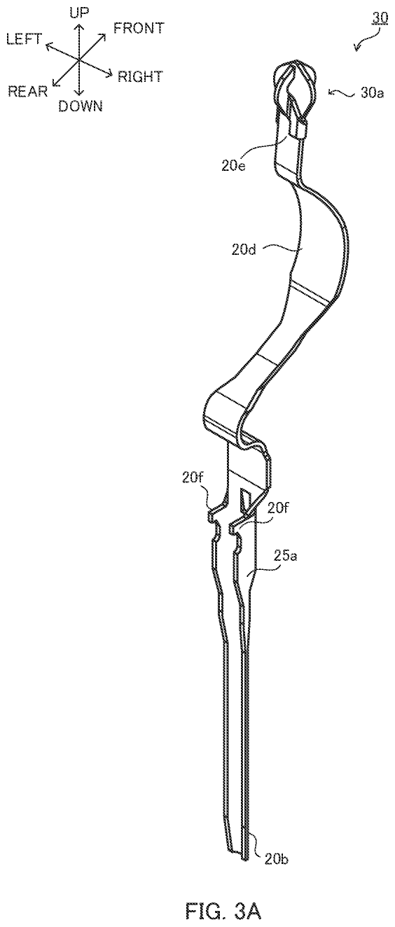

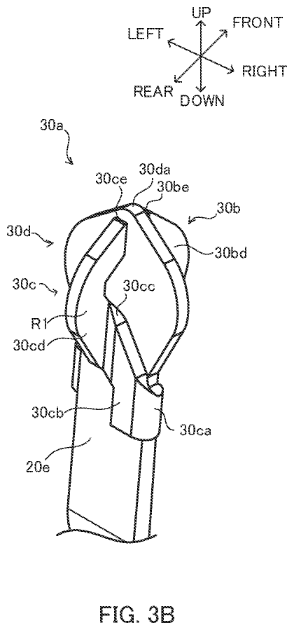

A configuration of a contact pin of a second embodiment of the present invention will be described with reference to FIGS. 3A and 3B. FIGS. 3A and 3B illustrate the configuration of the contact pin, in which FIG. 3A is an overall perspective view of the contact pin, and FIG. 3B is an enlarged perspective view of FIG. 3A to illustrate upper contact portion 30a (first contact portion).

As illustrated in FIGS. 3A and 3B, contact pin 30 has a configuration in which upper contact portion 20c of contact pin 20 (see FIG. 1) of the first embodiment is replaced with upper contact portion 30a. Moreover, in contact pin 30, press-fitting portion 20a of contact pin 20 of the first embodiment is replaced with press-fitting portion 25a having a small dimension in the front-rear direction compared with press-fitting portion 20a.

As illustrated in FIG. 3B, upper contact portion 30a includes first cut section 30b, second cut section 30c, and base piece 30d. First cut section 30b is continuously provided on the left end surface of the uppermost part of straight portion 20e, and second cut section 30c is continuously provided on the right end surface of the uppermost part of straight portion 20e. Base piece 30d extends upward from the uppermost part of straight portion 20e, and has a shape formed by joining an isosceles triangle to the top of a circle. First cut section 30b, second cut section 30c, and base piece 30d are formed thinner than the other portions of contact pin 30 and configured to be displaceable upward and downward.

Since first cut section 30b and second cut section 30c are symmetrical in front and rear and left and right, the configuration will be described in detail taking second cut section 30c as an example.

Second cut section 30c includes first portion 30cb on a side of base portion 30ca, and second portion 30cd on a tip side. Second cut section 30c is bent rearward (toward the rear surface of base piece 30d) at base portion 30ca, and first portion 30cb is overlapped on the rear surface of base piece 30d. Second cut section 30c is bent rearward at intermediate portion 30cc, and second portion 30cd is perpendicularly (or generally perpendicularly) opposite to the rear surface of base piece 30d.

Second portion 30cd includes a curved portion R1 having a generally arcuate shape in which the front end surface and rear end surface bulge rearward, and intermediate portion 30cc described above is placed closer to the base end side than curved portion R1 is. The tip of second portion 30cd is in contact with the front surface of base piece 30d at a position where upper end 30ce is slightly lower than upper end 30da of base piece 30d. In other words, upper end 30ce of second cut section 30c (and upper end 30be of first cut section 30b) is placed slightly below upper end 30da of base piece 30d. Further, second portion 30cd of second cut section 30c (and second portion 30bd of first cut section 30b) extends in the vertical direction when viewed from the front or rear. That is, each of second portions 30bd and 30cd is in a posture along the axial direction of contact pin 30.

Upper end 30ce, upper end 30be, and upper end 30da function as contact points that are brought into contact with pad 100a of IC package 100. Thus, upper end 30ce, upper end 30be and upper end 30da, hereinafter, are referred to as contact point 30ce, contact point 30be and contact point 30da, respectively.

Forming first cut section 30b and second cut section 30c into such a bent shape allows contact point 30ce and contact point 30be of the tips to be arranged adjacent to each other.

A description of the other configuration of contact pin 30 will be omitted because it is the same as contact pin 20 of the first embodiment. Further, the configuration of the socket will be also omitted because it is the same as socket 1 of the first embodiment, except for using contact pin 30.

### 2-2. Operational Effect

According to the second embodiment of the present invention, the following operational effects are obtained.

First cut section 30b, second cut section 30c and base piece 30d are individually displaceable in the vertical direction. Thus, when pressed by pad 100a of IC package 100, firstly, contact point 30da of base piece 30d is pressed by pad 100a to be elastically deformed and bent. Thereafter, contact point 30be of first cut section 30b and contact point 30ce of second cut section 30c are pressed. When the heights of contact points 30be and 30ce are different due to a manufacturing error, one of contact points 30be and 30ce is pressed by pad 100a.

Thus, according to the second embodiment of the present invention, since at least two contact points come into contact with pad 100a at the same time, as in the first embodiment, the conductivity of the contact pin can be improved than before, and contact pin 30 and socket 1 can support a high current.

### 2-3. Modification

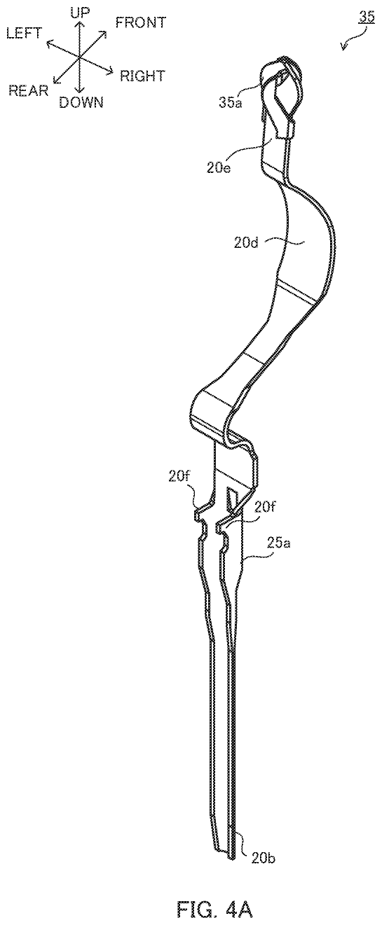

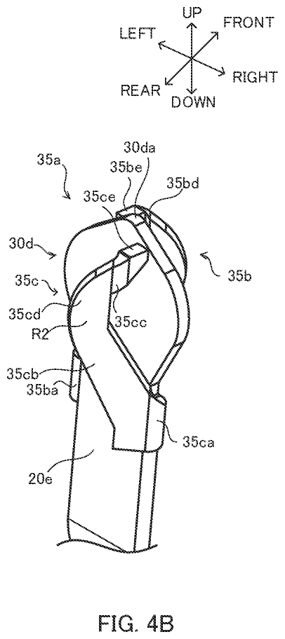

A configuration of a modification of the contact pin of the second embodiment of the present invention will be described with reference to FIGS. 4A and 4B. FIGS. 4A and 4B illustrate the configuration of the contact pin, in which FIG. 4A is an overall perspective view of the contact pin, and FIG. 4B is an enlarged perspective view of FIG. 4A to illustrate upper contact portion 35a (first contact portion).

Contact pin 35 illustrated in FIGS. 4A and 4B has a configuration in which upper contact portion 30a of contact pin 30 illustrated in FIGS. 3A and 3B is replaced with upper contact portion 35a, while first cut section 35b and second cut section 35c differ from first cut section 30b and second cut section 30c.

Since first cut section 35b and second cut section 35c are symmetrical in front and rear and left and right, the configuration will be described in detail mainly taking second cut section 35c as an example.

Second cut section 35c includes first portion 35cb on a side of base portion 35ca and second portion 35cd on a tip side. Second cut section 35c is bent rearward by only about 45 degrees at base portion 35ca (toward the rear surface of base piece 30d), and first portion 35cb faces the rear surface of base piece 30d at an interval. Second portion 35cd is bent by only about 45 degrees at intermediate portion 35cc so that the tip thereof is perpendicularly (or generally perpendicularly) opposite to the rear surface of base piece 30d.

Second portion 35cd includes curved portion R2 having a generally arcuate shape in which the front end surface and rear end surface bulge rearward. Intermediate portion 35cc described above is placed closer to the tip side than curved portion R2 is. A tip of second portion 35cd is placed on the right side and the lower side than contact point 30da, and, on its upper surface, contact point 35ce is provided in a projecting manner. Contact point 35ce has a rectangular shape which is long in front and rear when viewed from above.

First cut section 35b is bent forward by only about 45 degrees at base portion 35ba (toward the front surface of base piece 30d). Second portion 35bd on the tip side of first cut section 35b is bent by only about 45 degrees at the intermediate portion so that the tip thereof is perpendicularly (or generally perpendicularly) opposite to the front surface of base piece 30d. Second portion 35bd has a generally arcuate shape in which the front end surface and rear end surface bulge forward. The intermediate portion described above is placed on the tip side than the curved portion is. Second portion 35bd is placed on the left and lower side than contact point 30da, and, on its upper surface, contact point 35be is provided in a projecting manner. Contact 35be has a rectangular shape which is long in front and rear when viewed from above.

A description of the other configuration will be omitted because it is the same as contact pin 30 illustrated in FIGS. 3A and 3B. Further, the configuration of the socket will be also omitted because it is the same as socket 1 of the first embodiment, except for using contact pin 35.

### 3. Third Embodiment

### 3-1. Configuration

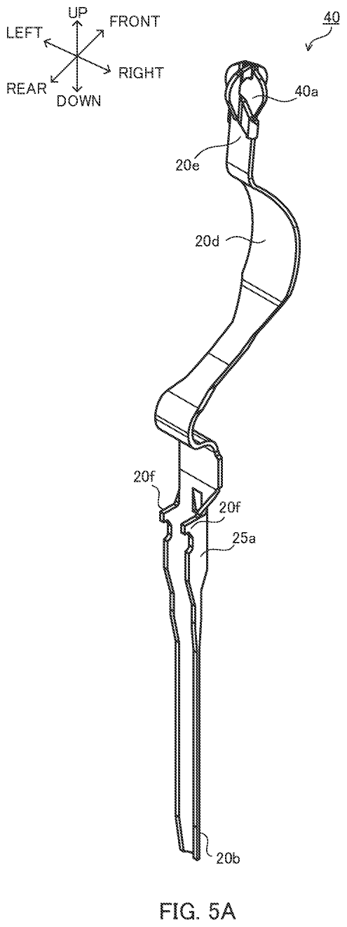

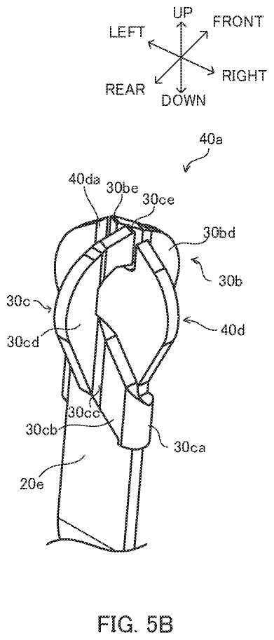

A configuration of a contact pin of a third embodiment of the present invention will be described with reference to FIGS. 5A and 5B. FIGS. 5A and 5B illustrate the configuration of the contact pin, in which FIG. 5A is an overall perspective view of the contact pin, and FIG. 5B is an enlarged perspective view of FIG. 5A to illustrate upper contact portion 40a (first contact portion).

Contact pin 40 of the third embodiment of the present invention illustrated in FIGS. 5A and 5B has a configuration in which upper contact portion 30a of contact pin 30 (see FIGS. 3A and 3B) of the second embodiment is replaced with upper contact portion 40a (first contact portion).

Specifically, base piece 40d includes on the upper part, with respect to base piece 30d of the second embodiment, cutout portion 40da which is recessed downward instead of contact point 30da. Notch portion 40da has a left side surface, a bottom surface and a right side surface. The tip lower surface of first cut section 30b (the portion directly below contact point 30be), and the tip lower surface of second cut section 30c (the portion directly below contact point 30ce), are arranged on the bottom surface of cutout portion 40da, or are arranged above the bottom surface with a slight gap from the bottom surface. Further, contact point 30be of first cut section 30b and contact point 30ce of second cut section 30c are arranged side by side in the width direction.

Note that, in the present embodiment, first cut section 30b is configured so that its tip does not exceed the rear surface of base piece 40d, but the tip may exceed the rear surface of base piece 40d. In other words, first cut section 30b may be configured to cross cutout portion 40da from the front. Similarly, second cut section 30c may be configured to cross cutout portion 40da from the rear.

A description of the other configuration will be omitted because it is the same as contact pin 30 of the second embodiment. Further, the configuration of the socket will be also omitted because it is the same as socket 1 of the first embodiment, except for using contact pin 40.

### 3-2. Operational Effect

According to the third embodiment of the present invention, the following operational effects are obtained in addition to the effects of the second embodiment. That is, the bottom surface of cutout portion 40da functions as a stopper for regulating an excessive downward displacement of first cut section 30b and second cut section 30c. Thus, when contact points 30be and 30ce of contact pin 40 are pressed by the IC package, it is possible to suppress first cut section 30b and second cut section 30c from being damaged including, for example, plastic deformation by excessive displacement.

### 4. Fourth Embodiment

### 4-1. Configuration

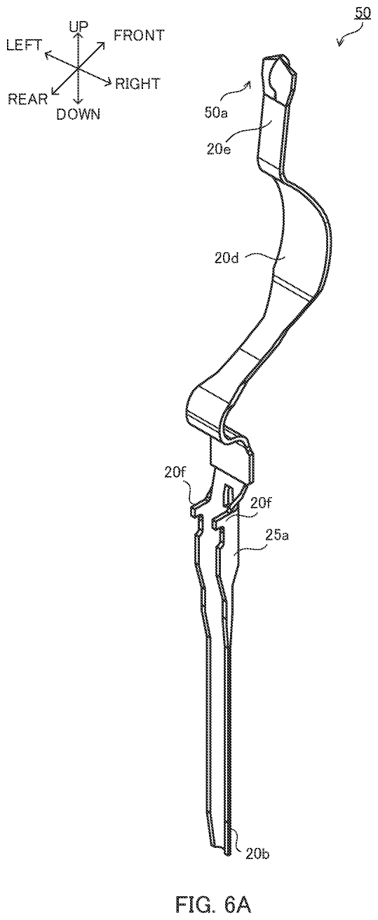

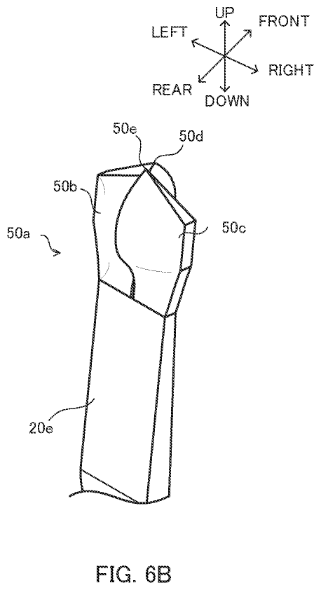

A configuration of a contact pin of a fourth embodiment of the present invention will be described with reference to FIGS. 6A and 6B. FIGS. 6A and 6B illustrate the configuration of the contact pin, in which FIG. 6A is an overall perspective view of the contact pin, and FIG. 6B is an enlarged perspective view of FIG. 6A to illustrate upper contact portion 50a (first contact portion).

As illustrated in FIGS. 6A and 6B, in contact pin 50, upper contact portion 50a includes first cut section 50b and second cut section 50c arranged side by side in the width direction. First cut section 50b has a shape in which an end part on a center side (right side) in the width direction of contact pin 50 and a front part thereof is pointed upward, and this apex functions as contact point 50d that comes into contact with pad 100a of IC package 100 (see FIG. 2). Second cut section 50c has a shape in which an end part on a center side (left side) of contact pin 50 in the width direction and a rear part thereof is pointed upward, and this apex functions as contact point 50e that comes into contact with pad 100a.

First cut section 50b is bent slightly forward with respect to straight portion 20e, while second cut section 50c is bent slightly rearward with respect to straight portion 20e. As a result, contact points 50d and 50e are arranged at positions shifted from each other in the front and rear direction. Moreover, first cut section 50b has a shallow bowl-like shape (curved shape) in which the front and rear surfaces are both bulging forward. Second cut section 50c, on the contrary, has a shallow bowl-like shape (curved shape) in which the front and rear surfaces both bulge rearward.

Further, first cut section 50b and second cut section 50c are formed thinner than the other portions of contact pin 50 so as to be easily displaced.

A description of the other configuration will be omitted because it is the same as contact pin 30 of the second embodiment. Further, the configuration of the socket will be also omitted because it is the same as socket 1 of the first embodiment, except for using contact pin 50.

### 4-2. Operational Effect

Since contact pin 50 is configured as described above, when pressed by pad 100a, first cut section 50b is curved so as to bulge forward, while second cut section 50c is curved so as to bulge rearward, and thus, first cut section 50b and second cut section 50c are displaced in the vertical direction individually.

Thus, according to the fourth embodiment of the present invention, in addition to obtaining the same effect as that of the first embodiment, since first cut section 50b and second cut section 50c are curved so as to bulge in directions opposite to each other, pad 100a can be received in a balanced manner.

### 5. Others

The contact pin and the socket of the present invention are applied to inspection of an IC package in each of the embodiments, but the contact pin and the socket of the present invention are not limited to this and can be applied to inspection of another electrical component or other various applications.

This application claims priority based on Japanese Patent Application No. 2018-203016, filed on Oct. 29, 2018, the entire contents of which including the specification and the drawings are incorporated herein by reference.

### INDUSTRIAL APPLICABILITY

The present invention may be suitably used as a contact pin and a socket.

### REFERENCE SIGNS LIST

1 Socket
10 Floating plate
10a Through hole
15 Base member (support)
15a Through hole
20, 30, 35, 40, 50 Contact pin
20a, 25a Press-fitting portion
20b Lower contact portion (second contact portion)
20c Upper contact portion (first contact portion)
20d Curved spring portion (spring portion)
20e Straight portion
20f Stopper piece
20g First cut section
20h Second cut section
20i Contact point
20j Contact point
30a Upper contact portion (first contact portion)
30b First cut section
30bd Second portion
30be Contact point
30c Second cut section
30ca Base portion
30cb First portion
30cc Intermediate portion
30cd Second portion
30ce Contact point
30d Base piece
30da Upper end
35a Upper contact portion (first contact portion)
35b First cut section
35ba Base portion
35bd Second portion
35be Contact point
35c Second cut section
35ca Base portion
35cb First portion
35cc Intermediate portion
35cd Second portion
35ce Contact point
40d Base piece
40da Notch portion
50a Upper contact portion (first contact portion)
50b First cut section
50c Second cut section
50d, 50e Contact point
100 IC package
100a Pad
200 Wiring board
R1, R2 Curved portion

What is claim is:

1. A contact pin, comprising:
a first contact portion provided on one end side in a first direction;
a second contact portion provided on another end side in the first direction; and
an elastically deformable spring portion provided on a middle portion between the first contact portion and the second contact portion, wherein
the first contact portion, the second contact portion, and the middle portion are integrally formed, and
the first contact portion includes a plurality of cut sections each being displaceable in the first direction.

2. The contact pin according to claim 1, wherein
each of the plurality of cut sections has a curved shape such that tips thereof are adjacent to each other, and includes a contact point provided on the one end side in the first direction of the tips.

3. The contact pin according to claim 2, wherein
the contact pin has a width in a second direction that intersects the first direction, and
as the plurality of cut sections, a first cut section provided on one end side in the second direction and a second cut section provided on another end side in the second direction are provided.

4. The contact pin according to claim 3, wherein
the first contact portion has a cylindrical shape by the first cut section and the second cut section formed in an arc shape.

5. The contact pin according to claim 3, wherein
the first contact portion further includes a base piece extending farther than a base portion of the first cut section and a base portion of the second cut section toward the one end in the first direction;
the first cut section is bent at the base portion to one surface of the base piece and is bent at an intermediate portion so that a tip faces the one surface,
the second cut section is bent at the base portion to another surface of the base piece and is bent at an intermediate portion such that a tip faces the other surface, and
a second portion of the first cut section and a second portion of the second cut section respectively have curved shapes such that the tips of the first cut section and the second cut section approach the base piece.

6. The contact pin according to claim 5, wherein
the base piece includes a cutout portion on the one end side in the first direction, and
the second portion of the first cut section and the second portion of the second cut section are individually arranged in the cutout portion.

7. The contact pin according to claim 1, wherein
the contact pin has a width in a second direction that intersects the first direction and has a thickness in a third direction that intersects the first direction and the second direction,
as the plurality of cut sections, a first cut section and a second cut section provided side by side in the second direction, and
the first cut section and the second cut section are inclined in directions opposite to each other in the third direction.

8. A socket, comprising:
the contact pin according to claim 1; and
a support including a through hole into which the contact pin is inserted.
